(19) United States
(12) Patent Application Publication
(10) Pub. No.: US 2023/0187390 A1
(43) Pub. Date: Jun. 15, 2023

(54) SEMICONDUCTOR DIE WITH DISSOLVABLE METAL LAYER

(71) Applicant: TEXAS INSTRUMENTS INCORPORATED, Dallas, TX (US)

(72) Inventors: Sebastian MEIER, Munich (DE); Bernhard ZIEGLTRUM, Freising (DE); Helmut RINCK, Gammelsdorf (DE)

(21) Appl. No.: 17/957,352

(22) Filed: Sep. 30, 2022

Related U.S. Application Data
(60) Provisional application No. 63/289,658, filed on Dec. 15, 2021.

(51) Int. Cl. H01L 23/00

(52) U.S. Cl. CPC H01L 24/05; H01L 24/32; H01L 24/16; H01L 24/73; H01L 24/08; H01L 2224/73204; H01L 2224/16227; H01L 2224/16237; H01L 2224/16257; H01L 2224/32225; H01L 2224/32245; H01L 2224/05657; H01L 2224/05111; H01L 2224/05169; H01L 2224/05541; H01L 2224/08502; H01L 2224/26145; H01L 2224/26175; H01L 2924/1461

(57) ABSTRACT

In one example, a semiconductor die comprises: a semiconductor substrate having a circuit formed therein; one or more metal layers on the semiconductor substrate, the one or more metal layers coupled to the circuit; a metal interface structure on the one or more metal layers, in which the metal interface structure has opposite first and second surfaces, and the first surface faces the one or more metal layers; and a dissolvable metal layer on the second surface.

### CROSS-REFERENCE TO RELATED APPLICATIONS

The present application claims priority to U.S. Provisional Patent Application No. 63/289,658, which was filed Dec. 15, 2021, is titled “COBALT SACRIFICIAL LAYER FOR SENSORS,” and is hereby incorporated herein by reference in its entirety.

### BACKGROUND

Semiconductor wafers comprise a semiconductor material, such as silicon or gallium nitride. Multiple circuits may be formed on a semiconductor wafer. The semiconductor wafer may be singulated to produce multiple semiconductor dies, with each die having its own circuitry. Each semiconductor die may include various components, such as a microelectromechanical system (MEMS), or an optical element, that are coupled to the circuitry in the die by way of metallization (e.g., a network of metal layers) formed on the die. Further, each semiconductor die may include a metal interface structure, such as bond pads and bumps, that are coupled to the circuitry in the die by way of the metallization. A semiconductor die may then be coupled to a package, a printed circuit board (PCB), or any other substrate using the metal interface structure.

### SUMMARY

In accordance with at least one example of the disclosure, a semiconductor die comprises a semiconductor substrate, one or more metal layers, a metal interface structure, and a dissolvable metal layer. The semiconductor substrate has a circuit formed therein. The one or more metal layers are on the semiconductor substrate and are coupled to the circuit. The metal interface structure has opposite first and second surfaces, and the first surface faces the one or more metal layers. The dissolvable metal layer is on the second surface.

In accordance with at least one example of the disclosure, an electronic device comprises a substrate, a semiconductor die, a solder layer, and an alloy metal interconnect. The substrate has a conductive terminal. The semiconductor die includes a metal interface structure. The solder layer is coupled to the conductive terminal of the substrate. The alloy metal interconnect is coupled between the metal interface structure and the solder layer, the alloy metal interconnect including an alloy of solder and cobalt.

In accordance with at least one example of the disclosure, a method comprises: forming circuitry in a semiconductor substrate, and forming one or more metal layers on the semiconductor substrate, the one or more metal layers coupled to the circuitry. The method further comprises forming a metal interface structure on the one or more metal layers, in which the metal interface structure has opposite first and second surfaces, the first surface faces and is coupled to the one or more metal layers. The method further comprises depositing a dissolvable metal layer on the second surface.

In accordance with at least one example of the disclosure, a method comprises: receiving a semiconductor die including a circuit, one or more metal layers coupled to the circuit, and a bond pad coupled to the one or more metal layers, the bond pad having opposite first and second surfaces, the first surface facing the one or more metal layers; and depositing a dissolvable metal layer on the second surface.

### BRIEF DESCRIPTION OF THE DRAWINGS

FIG. 1A is a schematic of top view of a semiconductor die having a dissolvable metal layer, in accordance with various examples.

FIG. 1B is a schematic of a perspective view of the example semiconductor die of FIG. 1A, in accordance with various examples.

FIG. 1C is a schematic of a cross-sectional view of the example semiconductor die of FIG. 1A, in accordance with various examples.

FIG. 2A is a schematic of a cross-sectional view of an electronic system including a substrate coupled to a semiconductor die having a dissolvable metal layer, in accordance with various examples.

FIG. 2B is a schematic of a top view of the example electronic system of FIG. 2A, in accordance with various examples.

FIG. 2C is a schematic of a perspective view of the example electronic system of FIG. 2A, in accordance with various examples.

FIG. 2D is a schematic of a bottom view of the example electronic system of FIG. 2A, in accordance with various examples.

FIGS. 3A, 3B, and 3C are schematics illustrating an example solder reflow process, in accordance with various examples.

FIGS. 4, 5, and 6 are schematics of example metal interconnects between a substrate and a semiconductor die, in accordance with various examples.

FIG. 7 is a block diagram of an electronic system, in accordance with various examples.

FIG. 8 is a flow diagram of an example method for manufacturing an electronic system in accordance with various examples.

FIGS. 9A-9D are schematics that illustrate some of the operations of the example method of FIG. 8, in accordance with various examples.

### DETAILED DESCRIPTION

Semiconductor die can include metal interface structures to provide access to various components in or on the semiconductor die. Examples of such metal interface structures include bond pads and bumps. The metal interface structure can be part of or bonded to a metal interconnect between the semiconductor die and a substrate, which can be part of a semiconductor package (e.g., lead frame) or a PCB. The metal interconnect can include solder bumps, bond wires, etc., and can be bonded to the metal interface structure via the formation of a solder joint between the metal interface structure and the metal interconnect.

The metal interface structure, such as bond pad and bump, may include various types of metal elements. Some metal elements, such as copper and aluminum, are prone to corrosion, which can compromise the mechanical and functional integrity of the semiconductor die. Some metal elements, such as platinum group metals (e.g., platinum, ruthenium, rhodium, palladium, osmium, iridium), are corrosion-resistant. But these elements are prone to forming thin oxide layers on the bond pad surface. The thin oxide layers can resist solder wetting and prevent the bonding between the bond pad and other structures (e.g., package lead frames, PCBs) using a solder reflow process. This can limit the application of corrosion-resistant bond pads, such as flip-chip applications in which a device side of a semiconductor die (the side of the die in which circuitry is formed) is coupled to a lead frame or PCB using a solder reflow process while facing the lead frame or PCB.

Furthermore, semiconductor dies may have sensitive components that are vulnerable to physical damage. The physical damage can be caused by, for example, scratching or chipping by environmental debris, chemical cleaning during a packaging process, or strong air flow during a drying process. Examples of such components can include MEMS (e.g., sensor, mirror, and actuator) and various optical/photonic elements (e.g., photodiode, light emitting diode, and waveguide). The handling of those semiconductor dies, and the mounting of the semiconductor dies to lead frames or PCBs, can be subject to various constraints to avoid damaging the dies' sensitive components and to provide clearance so that the sensitive components can perform their target functions (e.g., to reflect light or to sense properties such as air flow, humidity, and chemical composition). These constraints, and the corrosion and solder wetting properties of the bond pads, can increase the complexity of the manufacturing process of electronic systems including the semiconductor dies, and affect the reliability of those systems.

This disclosure describes techniques that can mitigate the challenges described above. In particular, a semiconductor die includes a semiconductor substrate (e.g., silicon substrate) having circuitry formed therein and metallization comprising a network of one or more metal layers coupled to the circuitry. The semiconductor die also includes a metal interface structure, such as a bond pad. The bond pad comprises a noble metal element that is solderable but resistant to solder wetting, such as platinum group metals (e.g., platinum, ruthenium, rhodium, palladium, osmium, iridium). In examples, the bond pad comprises a non-noble metal element that is solderable but resistant to solder wetting, such as aluminum, titanium, and titanium nitride. The bond pad has a first surface facing and coupled to the metallization and a second surface opposite the first surface. A dissolvable metal layer is on the second surface of the bond pad. In some examples, the dissolvable metal layer includes a solder wetting facilitator, such as cobalt, which facilitates diffusion between solder and the oxidized metal as the dissolvable metal layer dissolves. The dissolvable metal layer thus facilitates the formation of a metal interconnect including an alloy of solder and the dissolvable metal. In some examples, the metal interconnect can also include an alloy of solder, the dissolvable metal, and the bond pad metal.

In addition to being formed on bond pads of the semiconductor die, a dissolvable metal layer may also be positioned on a surface component (e.g., MEMS) of the semiconductor die, such as a mirror, a sensor, a photonic element, or an optical element. The surface component can be on a surface of a semiconductor substrate of the semiconductor die. The dissolvable metal layer protects the surface component from damage (e.g., such as from debris, gaseous or dissolved ionic materials, penetration of ions or radical gases, light, aggressive wet or dry chemical cleans during packaging, strong air flow (e.g., during a drying process), mechanical stress, and thermal stress until the semiconductor die has been coupled to a lead frame or PCB and is ready for use. The dissolvable metal layer, the surface component, and a metallization under the surface component can form a capacitor that can be used to characterize the surface component. Specifically, the capacitor may be charged by applying a voltage to the first metal plate of the capacitor (the dissolvable metal layer) and to the second metal plate of the capacitor (the metallization under the surface component, which is electrically accessible by way of a bond pad coupled to the metallization). The behavior of the capacitor may then be observed and compared to expected results to characterize the surface component. After any such characterization is completed and the surface semiconductor die has been coupled to a lead frame or PCB, the semiconductor die is ready to use, and thus the dissolvable metal layer may be removed (dissolved) using a suitable chemical, such as hydrochloric acid (HCl), or any other suitable technique, such as gaseous reactive etching. In addition to the technical advantages provided by the semiconductor die described herein, such as easy solder wetting, protection of surface components of the semiconductor die from damage, and capacitive characterization of surface components, the dissolvable metal layer reduces the amount of solder used to achieve strong solder joints, thus occupying less space than would otherwise be the case.

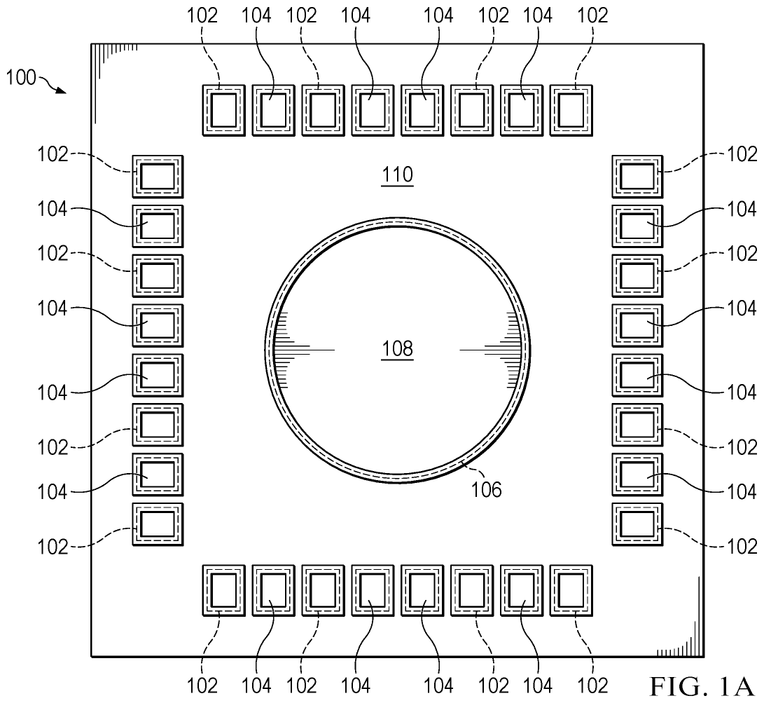

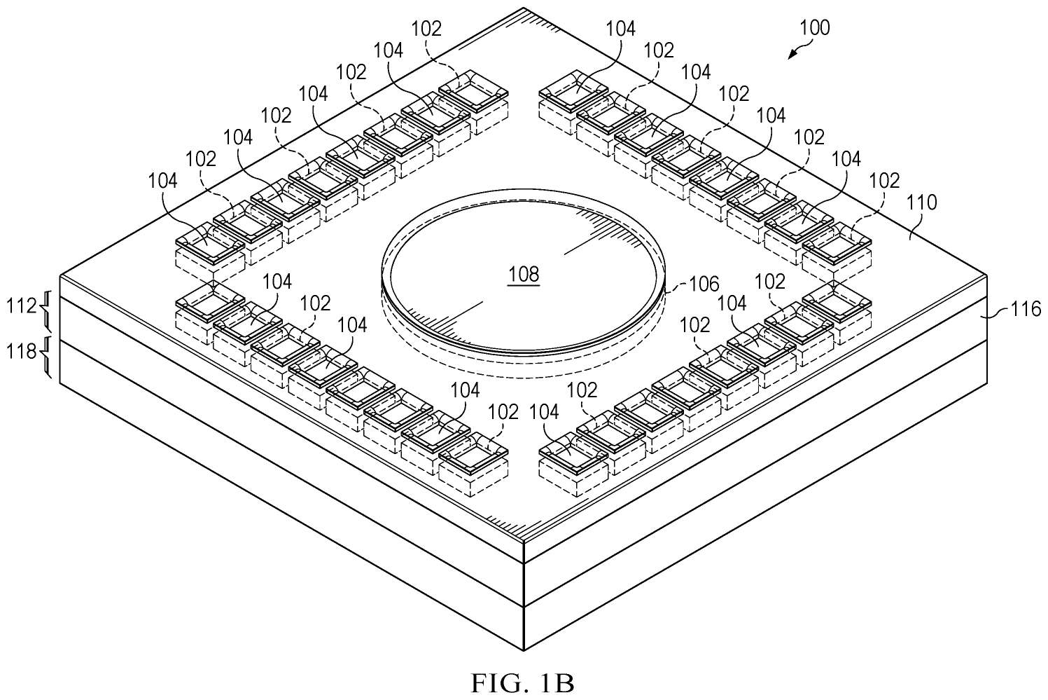

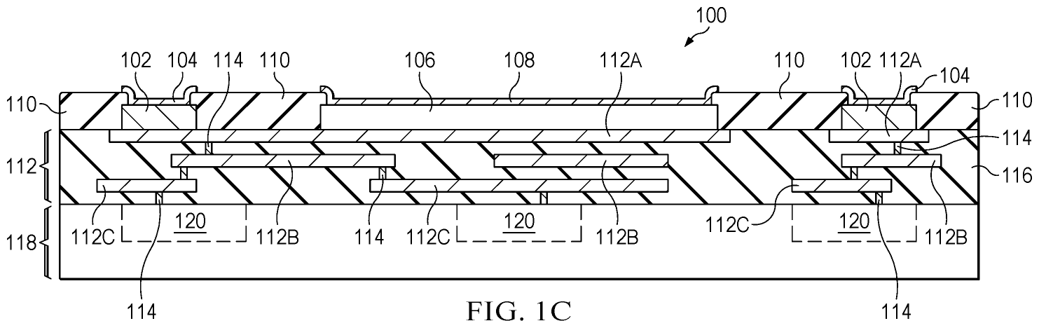

FIGS. 1A-C are schematics of a semiconductor die 100 having a dissolvable metal layer, in accordance with various examples. FIG. 1A provides a top view, FIG. 1B provides a perspective view, and FIG. 1C provides a cross-sectional view. Referring to FIGS. 1A-1C, the semiconductor die 100 includes a metal interface structure including multiple bond pads 102, each of which is at least partially covered by and abutting a dissolvable metal layer 104. In some examples, the bond pads 102 comprise a noble metal. In examples, the bond pads 102 comprise a noble metal such as platinum, ruthenium, rhodium, palladium, osmium, and iridium. In examples, the bond pads 102 comprise a non-noble metal capable of forming an alloy with solder, and, more specifically, with tin.

The semiconductor die 100 may also include a surface component 106 on a surface of a semiconductor substrate (e.g., semiconductor substrate 118) of the die. Surface component 106 can include MEMS (e.g., sensor, mirror, and actuator) and various optical/photonic elements (e.g., photodiode, light emitting diode, and waveguide). Surface component 106 can be at least partially covered by and abutting a dissolvable metal layer 108. In some examples, as shown in FIGS. 1A-1C, surface component 106 can be on the same surface/side of the semiconductor die 100, which allows dissolvable metal layers 104 and 108 to be formed simultaneously (or in a same operation) on the respective bond pads 102 and surface component 106. In some examples, surface component 106 and semiconductor die 100 can be on opposite surfaces/sides of semiconductor die 100, and dissolvable metal layers 104 and 108 can be formed on the respective bond pads 102 and surface component 106 in separate operations.

In some examples, each of dissolvable metal layers 104 and 108 can include a metal or a metal alloy capable of dissolving into solder, and, more specifically, capable of alloying with tin. The metal (or metal alloy) is also capable of dissolving in an acid (e.g., hydrochloric acid or a solution of phosphoric acid, nitric acid, acetic acid, and water) or in an etching reactant, so that dissolvable metal layers 104 and 108 can be removed to expose the underlying structure.

In some examples, dissolvable metal layers 104 and 108 include a solder wetting facilitator to facilitate bonding between the bond pad and a solder material. For example, the dissolvable metal layer can facilitate diffusion between solder and an oxide layer on the surface of the bond pad, if the bond pad includes a metal element that is prone to forming an oxide layer (e.g., platinum group metals). In some examples, the dissolvable metal layer can remove or disrupt the oxide layer, thereby making the bond pad metal more readily solderable. For example, after forming the dissolvable metal layers on semiconductor die 100, a partial removal of the dissolvable metal layer by an etching process (e.g., a sputter etch process with an inert gas such as Argon) can facilitate in-situ removal of the oxide layer.

Examples of dissolvable metal layers 104 and 108 can include cobalt, nickel, tin, or other metal elements/alloys having substantially the same solder wetting properties. In some examples, the dissolvable metal layers 104 and 108 can have the same material composition. In some examples, the dissolvable metal layers 104 and 108 have different material compositions. In some examples, the dissolvable metal layers 104 and 108 have a thickness ranging from 10 nanometers to 100 nanometers. In examples, the dissolvable metal layers 104, 108 have a thickness of less than 5 kilo Angstroms. In examples, the dissolvable metal layers 104, 108 are deposited by various thin film deposition techniques, such as physical vapor deposition (PVD) (e.g., sputtering), chemical vapor deposition (CVD), electroplating, etc. Other deposition techniques are contemplated and included in the scope of this disclosure.

As described above, surface components 106 may include MEMS (e.g., sensor, mirror, and actuator) and various optical/photonic elements (e.g., photodiode, light emitting diode, and waveguide). The MEMS sensor can be for measuring humidity, temperature, chemical properties, airflow, etc. Such components can include structures and surfaces that are prone to physical damage caused by, for example, scratching or chipping by environmental debris, chemical cleaning during a packaging process, or strong air flow during a drying process. By at least partially covering surface components 106 with dissolvable metal layers 108, they can be protected from the physical damage.

FIG. 1C provides a cross-sectional view of the semiconductor die 100, in accordance with various examples. The semiconductor die 100 includes the semiconductor substrate 118, such as silicon or gallium nitride. The substrate 118 has circuitry 120 formed therein. The circuitry 120 may perform any suitable function. In some examples, the circuitry 120 characterizes properties of materials detected by a sensor of the surface component 106. In some examples, the circuitry 120 controls mirrors of the surface component 106. A metallization layer 112 is positioned on the semiconductor substrate 118 and includes one or more metal layers. For example, the metallization layer 112 includes metal layers 112A, 112B, and 112C coupled by vias 114. The metal layer 112C is likewise coupled to the circuitry 120 by vias 114. In some examples, the surface component 106 can be between the dissolvable metal layer 108 and part of the metallization layer 112 (e.g., metal layers 112A and 112B). The metal layer 112A may be coupled to bond pads 102 and to surface component 106, thereby providing an electrical pathway between the bond pads 102 and the surface component 106. In some examples, the surface component 106 is coupled to fewer than all of the bond pads 102. The dissolvable metal layer 104 facilitates the formation of strong solder joints/bonding when the bond pads 102 are soldered to a substrate, such as a PCB (the substrate may be part of the PCB, or the PCB may be part of the substrate) or a package lead frame. The dissolvable metal layer 108 protects the surface component 106 from physical damage. An insulation layer 110, such as a passivation layer, may protect the metallization layer 112 from oxidative damage.

In some examples, described below, the dissolvable metal layer 108, the surface component 106, and the metal layer 112A can together form a capacitor to facilitate characterization of surface component 106. Various parameters indicative of the property of surface component 106 can be measured as part of the characterization. Such parameters can include time constant (which reflects time to charge or discharge to a particular charge level), leakage current, and alternating current characteristics such as frequency response, etc. These parameters can be compared to expected behavior or benchmark data to characterize surface component 106. In some examples, the characterization can be part of a quality control testing operation or a yield determination operation of the surface component 106.

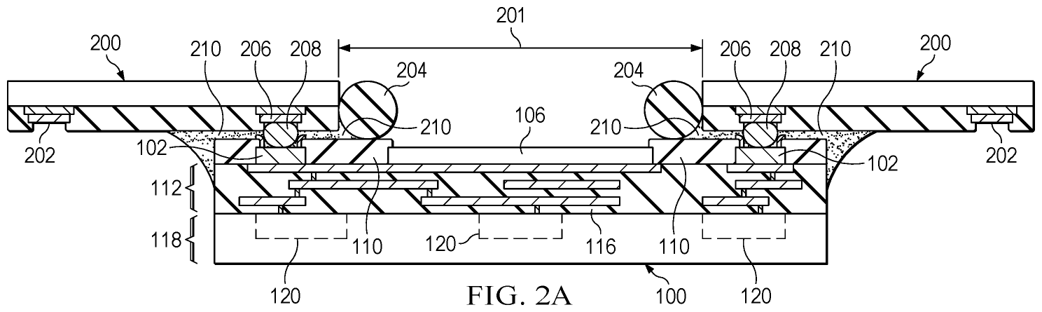

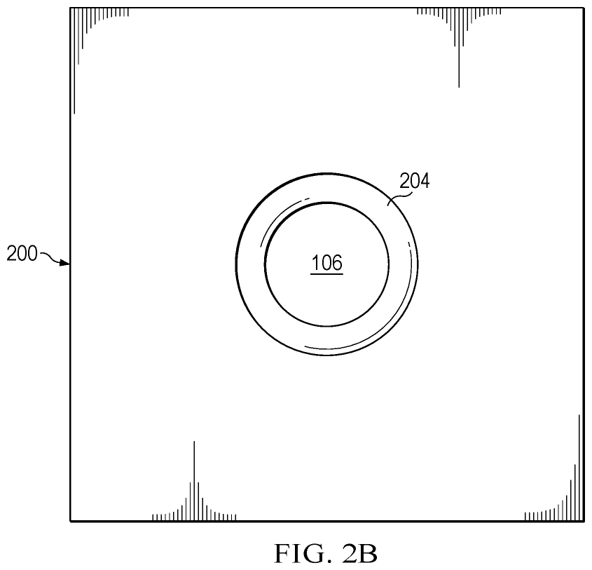

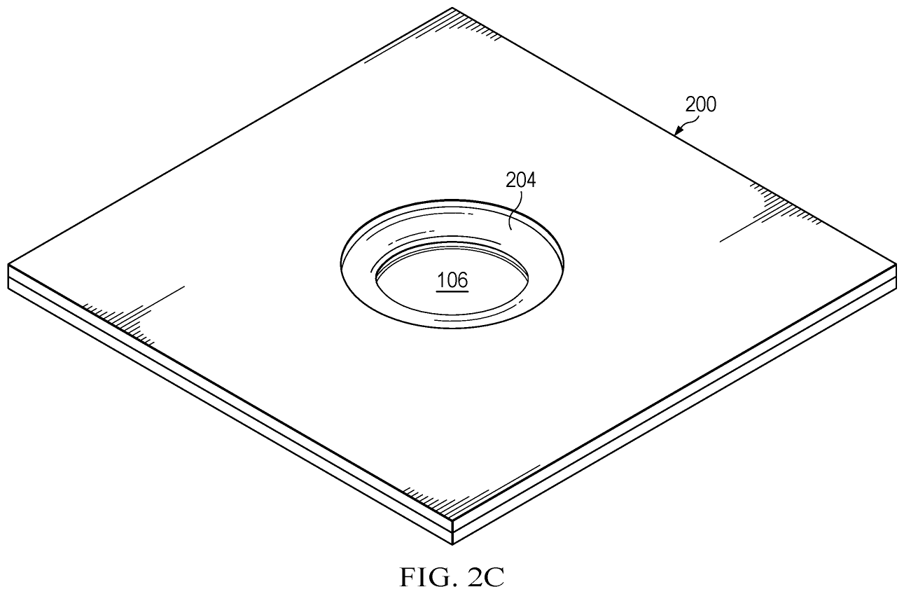

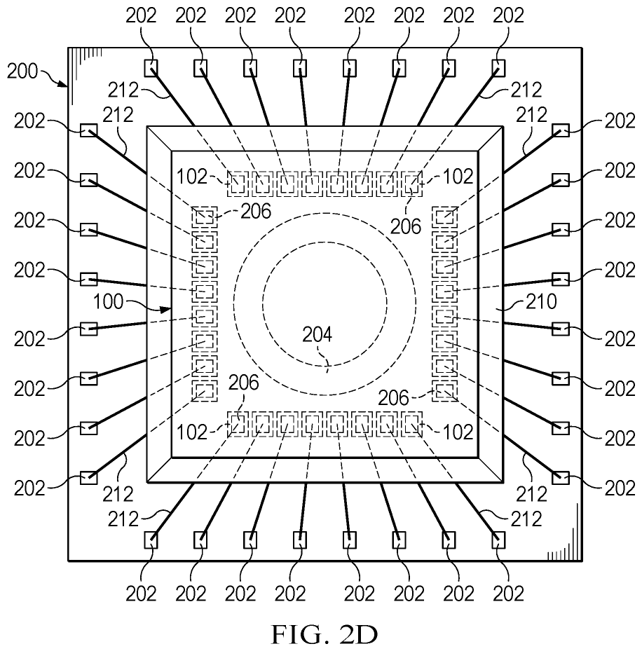

FIGS. 2A-2D are schematics of an electronic system including a substrate 200 coupled to the semiconductor die 100, in accordance with various examples. FIG. 2A provides a cross-sectional view, FIG. 2B provides a top view, FIG. 2C provides a perspective view, and FIG. 2D provides a bottom view. In examples, the substrate 200 is a semiconductor package lead frame. In examples, the substrate 200 is a PCB. Other types of substrates are contemplated and included in the scope of this disclosure. In some examples, the substrate 200 includes an orifice 201 and conductive terminals 202. Referring to FIG. 2D, conductive terminals 202 can be arranged in a rectangular pattern along a periphery of a device side of the substrate 200. The substrate 200 also includes conductive terminals 206 arranged in a rectangular pattern, away from the periphery of the device side of the substrate 200. For example, the conductive terminals 202 and the conductive terminals 206 may be concentric relative to each other. Each of the conductive terminals 206 can be coupled to a respective conductive terminal 202 by a metal trace 212.

The semiconductor die 100 is coupled to the substrate 200. For instance, the bond pads 102 of the semiconductor die 100 are coupled to the conductive terminals 206 of the substrate 200 by solder joints 208. The coupling between the bond pads 102 and the conductive terminals 206 is described in greater detail below. Also, the surface component 106 is aligned with the orifice 201 of the substrate 200, such that the surface component 106 is accessible or exposed through the orifice 201. In examples, a rubber o-ring 204 abuts the substrate 200 and the semiconductor die 100 to form a seal around orifice/opening 201 surface component 106. An underfill 210 between substrate 200 and semiconductor die 100 can reinforce the sealing. In some examples, the surface component 106 can interact with the environment (e.g., to sense light, fluid, pressure, etc.) via opening 201 and convey the sensed information to circuitry 120 (FIG. 1C) in the semiconductor die 100. The circuitry 120, in turn, provides information relating to the information from the MEMS surface component 106 to the bond pads 102, and the bond pads 102 provide this information to the substrate 200 (e.g., PCB) by way of the conductive terminals 206. The substrate 200, in turn, provides the information to another structure (e.g., a chip) by way of the conductive terminals 202. In some examples, the surface component 106 can also move responsive to an electrical signal provided by circuitry 120, which generates the electrical signal responsive to information received via conductive terminals 202.

In some examples, substrate 200 may not include orifice/opening 201. In examples where the bond pads 102 and the surface component 106 are on the same side of semiconductor die 100, the semiconductor die can be positioned on substrate 200, with the bond pads 102, the surface component 106, and the conductive terminals 206 facing the same direction away from the substrate 200. The bond pads 102 and the conductive terminals 206 can be coupled via bond wires. The bond wires can be bonded to the bond pads 102 by solder joints 208. In examples where the bond pads 102 and the surface component 106 are on opposite sides of semiconductor die 100, the bond pads 102 can be facing the conductive terminals 206 and can be coupled via solder joints 208, and the surface component 106 faces away from the substrate 200.

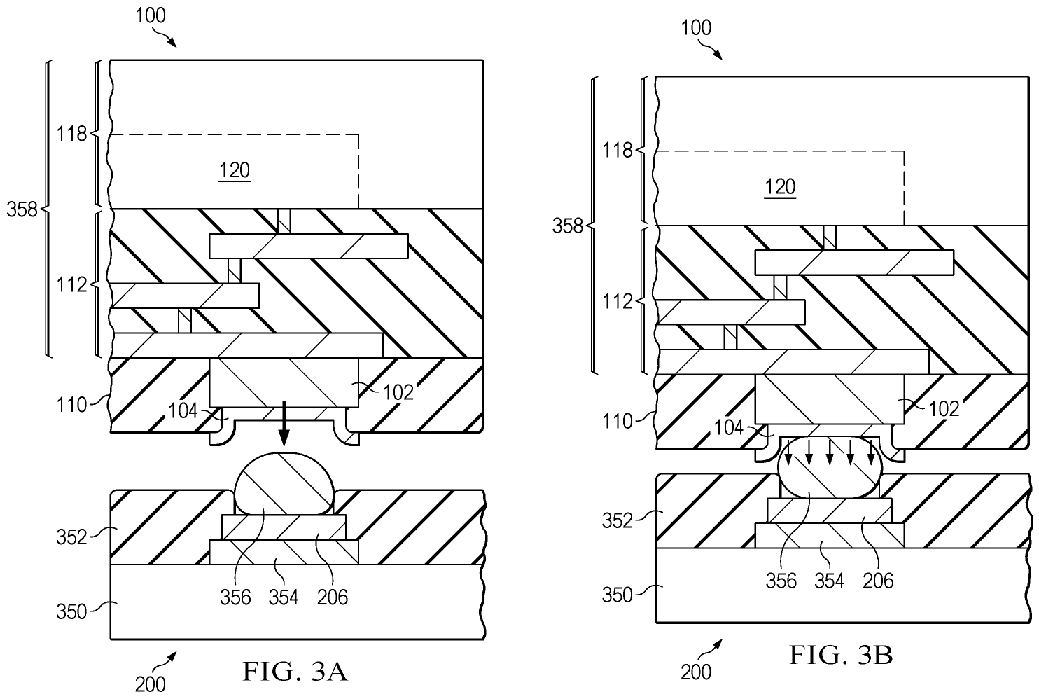

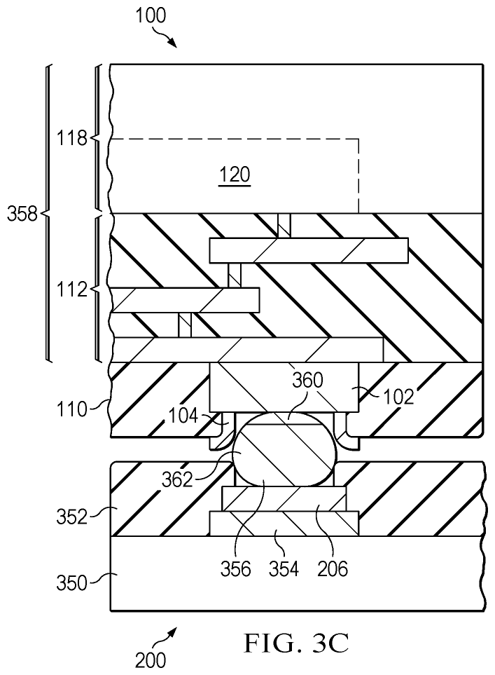

FIGS. 3A-3C are schematics of an example solder reflow process to create solder bonding between the substrate 200 to the semiconductor die 100, in accordance with various examples. Referring to FIG. 3A, the substrate 200 includes a body 350 and an insulation layer 352 (e.g., passivation layer) abutting the body 350. A metal layer 354, such as one of the metal traces 212, couples to the body 350. Conductive terminal 206, which can include a metal plating such as, electroless nickel/electroless palladium/immersion gold (ENEPIG) plating, is coupled to the metal layer 354. A solder member 356 (e.g., a pre-printed solder member) is coupled to the conductive terminal 206. The semiconductor die 100 includes a body 358, which includes, for example, the semiconductor substrate 118 and the metallization layer 112 (of FIG. 1C). The semiconductor die 100 also includes the insulation layer 110 abutting the body 358. The bond pad 102 abuts the body 358 and can be at least partially covered by (and deposited thereon) the dissolvable metal layer 104 (e.g., cobalt). In examples, the dissolvable metal layer 104 abuts the bond pad 102 as well as a portion of the insulation layer 110 on some or all sides of the bond pad 102.

Referring to FIG. 3B, the solder member 356 and the dissolvable metal layer 104 are brought into contact with each other. Heat is applied to begin reflowing the solder member 356, which causes the dissolvable metal layer 104 to dissolve into the solder member 356 and form an alloy with one or more of the metal elements in the solder member 356 (e.g., with tin).

Referring to FIG. 3C, the solder reflow process is complete, and at least part of the dissolvable metal layer 104 has dissolved into the solder member 356. Some portions of the dissolvable metal layer 104, such as the portions not touching the solder member 356, may remain undissolved. As shown, the solder member 356 now has formed a solder joint that includes multiple layers. Specifically, in FIG. 3C, the bond pad 102 abuts an alloy layer 360 of the bond pad 102 metal (e.g., platinum), solder, and the dissolvable metal (e.g., cobalt). The alloy layer 360 abuts an alloy layer 362 of solder and the dissolvable metal (e.g., cobalt). The concentration of the dissolvable metal in the alloy layer 362 may be greater than the concentration of the dissolvable metal in the alloy layer 360. In examples, the concentration of the dissolvable metal in the alloy layers 360 and/or 362 is in the parts-per-million (PPM) range.

Because the dissolvable metal layer 104 facilitates solder wetting, less solder can be used to form a strong solder joint. And because less solder is used, the distance between the bond pad 102 and the conductive terminal 206 can be reduced (e.g., less than 10 microns). This can reduce the form factor for the semiconductor die and substrate assembly, which is advantageous, particularly in applications in which small form factors are desirable (e.g., smartphones).

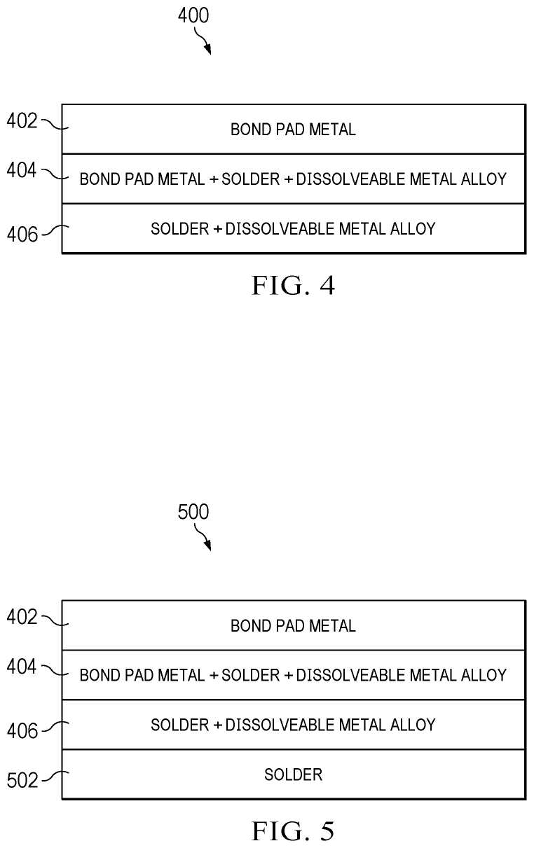

FIGS. 4-6 are schematic diagrams depicting example metal interconnects between the semiconductor die 100 and the substrate 200. The example metal interconnects of FIGS. 4-6 can include a solder joint formed from the example reflow process of FIGS. 3A-3C. The example metal interconnects of FIGS. 4-6 can be further coupled to other metal interconnects not shown in the figures, such as bond wire. Referring to FIG. 4, an example metal interconnect 400 includes a bond pad metal (e.g., platinum) 402 coupled to an alloy layer 404 of the bond pad metal, solder, and the dissolvable metal (e.g., cobalt). The alloy layer 404 is coupled to an alloy layer 406 of solder and the dissolvable metal. Referring to FIG. 5, an example metal interconnect 500 includes the same layers 402, 404, and 406 of FIG. 4, and a solder layer 502 abutting the alloy layer 406 of solder and the dissolvable metal. The additional layer of solder may be present where, for example, the dissolvable metal does not penetrate fully into the solder member 356.

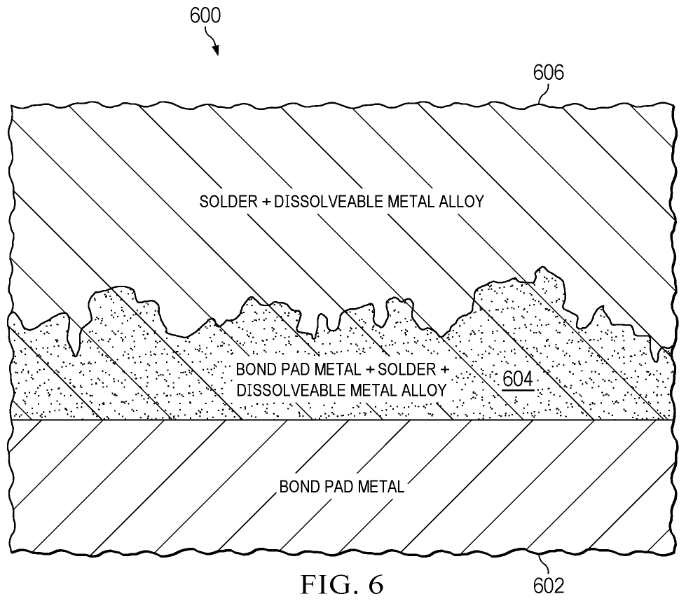

FIG. 6 provides an illustration of a metal interconnect 600 including a tin (solder) layer 606, a platinum layer (Pt) 602, and an alloy 604 of tin and platinum positioned between layers 602 and 606. Because both the tin layer and the alloy layer include the dissolvable metal (not expressly shown due to low PPM concentrations), the tin layer may be referred to as an alloy of tin and the dissolvable metal, and the alloy layer of tin and platinum may be referred to as an alloy of tin, platinum, and the dissolvable metal, as in FIG. 6.

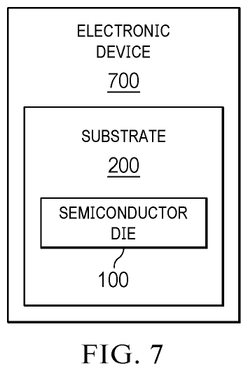

FIG. 7 is a block diagram of an electronic system 700, in accordance with various examples. The electronic system 700 may be any suitable type of device, such as a desktop computer, a laptop computer, a notebook, an e-reader, a tablet, an appliance, an automobile, an aircraft, a spacecraft, a medical device, etc. The electronic system 700 may include the substrate 200, such as a PCB. The electronic system 700 may include the semiconductor die 100 coupled to the substrate 200.

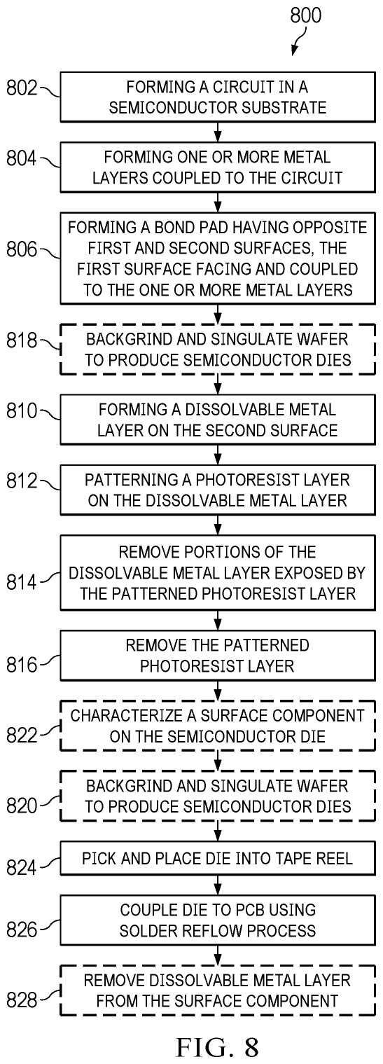

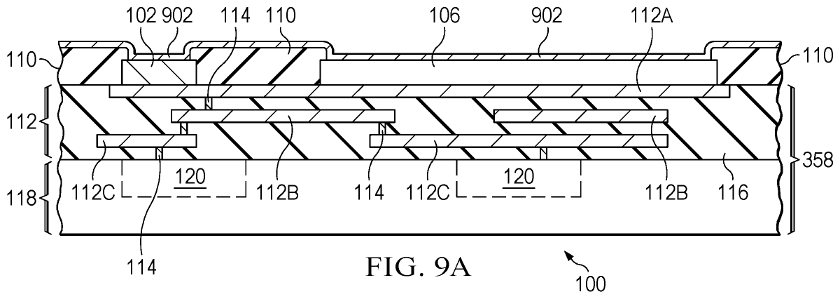

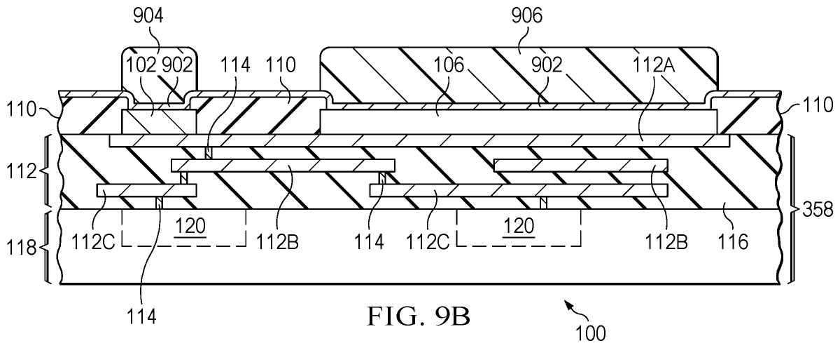

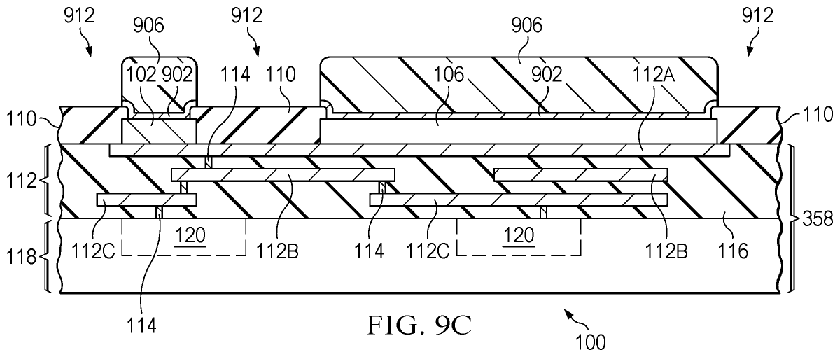

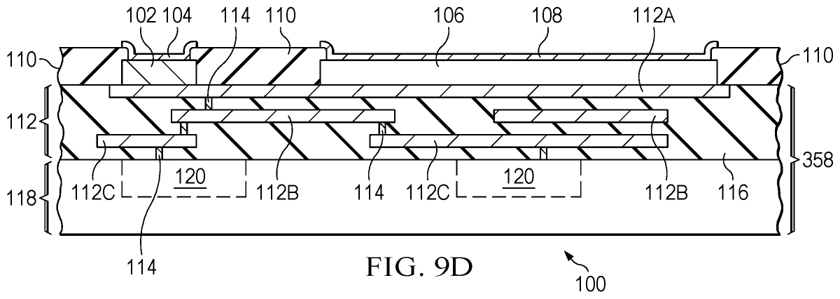

FIG. 8 is a flow diagram of an example method 800 for manufacturing an electronic system in accordance with various examples. FIGS. 9A-9D are schematics that illustrate some of the operations of the example method 800.

In operation 802, a circuit (e.g., circuitry 120) can be formed in a semiconductor substrate. Also, in operation 804, one or more metal layers can be formed on the semiconductor substrate, in which the one or more metal layers are coupled to the circuit (304). Further, in operation 806, a metal interface structure, such as bond pad having opposing first and second surfaces, can be formed, in which the first surface faces and is coupled to the one or more metal layers (306). Surface component 106, such as MEMS, a photonic element, or an optical element, can also be formed on semiconductor substrate as part of operations 802-806 or in a separate operation. Operations 804 and 806 may be performed in the wafer stage of manufacture as part of a wafer-level processing operation, or may be performed on individual semiconductor die after singulation.

In operation 810, a dissolvable metal layer can be formed on the second surface and on the surface component 106. The dissolvable metal layer can be formed using various thin film deposition techniques, such as physical vapor deposition (PVD) (e.g., sputtering), chemical vapor deposition (CVD), electroplating, etc. In some examples, two dissolvable metal layers can be formed on the respective second surface and the surface component 106 in separate operations, such as in a case where the metal interface structure (e.g., bond pad) and the surface component 106 are on opposite sides of the semiconductor die 100.

FIG. 9A depicts an example semiconductor die 100 having the body 358, the bond pad 102 coupled to the body 358, and the surface component 106 coupled to the body 358. The dissolvable metal layer 902 abuts and covers the bond pad 102 and the MEMS surface component 106. The dissolvable metal layer 902 can also abut/cover the insulation layer 110. If the dissolvable metal layer 104 is deposited in the wafer stage, the dissolvable metal layer 104 may cover the entirety of the wafer. If the dissolvable metal layer 902 is deposited on an individual semiconductor die after wafer singulation, the dissolvable metal layer 902 may cover the entirety of the semiconductor die.

In operation 812, a photoresist layer can be deposited on the dissolvable metal layer 902, followed by patterning the photoresist layer. The patterning can be performed by photolithography followed by removal of some of photoresist layer by a developing solution. FIG. 9B illustrates an example of a photoresist layer 904 covering a portion of the dissolvable metal layer 902 that covers the bond pad 102, and a photoresist layer 906 covering a portion of the dissolvable metal layer 902 that covers the surface component 106, after the patterning operation. Both the photoresist layers 904 and 906 can also cover portions of the insulation layer 110.

In operation 814, portions of the dissolvable metal layer 902 exposed by the photoresist layers 904 and 906 can be removed by an etching operation. The etching can be performed by a wet etching operation or a dry etching operation. FIG. 9C illustrates the result of the etching operation. Referring to FIG. 9C, segments of the dissolvable metal layer 902 exposed by the photoresist layers 904 and 906 are removed, as indicated by numerals 912. Thus, the bond pad 102, the surface component 106, and portions of the insulation layer 110 can remain covered by the dissolvable metal layer 902.

In operation 816, the patterned photoresist layer (e.g., photoresist layers 904 and 906) can be removed. The patterned photoresist layer may be removed using any suitable solvent, such as 1-methyl-2-pyrrolidone (NMP), or using an oxygen plasma ash. FIG. 9D illustrates the result of operation 816. With the photoresist layers 904 and 906 removed, a first patterned dissolvable metal layer 902 is formed on the bond pad 102 as the dissolvable metal layer 104, and a second patterned dissolvable metal layer 902 is formed on the surface component 106 as the dissolvable metal layer 108.

Method 800 also includes an operation to backgrind and singulate the wafer to produce individual semiconductor dies. In some examples, the backgrinding and singulation operation can be performed prior to operations 810-816, as represented by operation 818. In some examples, the backgrinding and singulation operation can be performed after operations 810-816, as represented by operation 820.

Optionally, method 800 can include an operation 822 to characterize the surface component 106 as described above. Specifically, referring to FIG. 8D, the bond pad 102 may be coupled to the surface component 106 by way of a metal layer in the body 358. Dissolvable metal layer 108, the surface component 106, and the metal layer in the body 358 abutting the surface component 106 can form a capacitor. Operation 822 can include applying a voltage signal across dissolvable metal layer 108 and the metal layer in the body 358, and measuring various parameters, such as time constant, frequency response, etc. In this way, the surface component 106 may be tested as part of the manufacturing process. Operation 822 can be performed before or after the backgrinding and singulation operation (represented by operation 818 and 820 in FIG. 8).

Method 800 also includes operation 824, in which individual semiconductor dies are picked and placed (e.g., into a tape reel), and operation 826, in which the semiconductor dies are mounted to PCBs or other substrates using the solder reflow processes described above. Optionally, method 800 can include operation 828, in which the dissolvable metal layer 108 can be removed from the surface component 106 using a chemical agent, such as hydrochloric acid (HCl), a 16:1:1:2 solution of phosphoric acid, nitric acid, acetic acid, and water, and an etching reactant.

In some examples, a method comprises receiving a semiconductor die including a circuit, one or more metal layers coupled to the circuit, and a bond pad coupled to the one or more metal layers, the bond pad having opposite first and second surfaces, the first surface facing the one or more metal layers; and depositing a dissolvable metal layer on the second surface. The semiconductor die can be fabricated from operations 802-806 and 818 of method 800. The deposition of the dissolvable metal layer on the second surface can be performed based on operation 810 of method 800.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A device that is described herein as including certain components may instead be coupled to those components to form the described device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies.

Unless otherwise stated, “about,” “approximately,” or “substantially” preceding a parameter means being within +/−10 percent of that parameter. Modifications are possible in the described examples, and other examples are possible within the scope of the claims.

What is claimed is:

1. A semiconductor die, comprising:
a semiconductor substrate having a circuit formed therein;
one or more metal layers on the semiconductor substrate, the one or more metal layers coupled to the circuit;
a metal interface structure on the one or more metal layers, in which the metal interface structure has opposite first and second surfaces, and the first surface faces the one or more metal layers; and
a dissolvable metal layer on the second surface.

2. The semiconductor die of claim 1, wherein the metal interface structure includes a bond pad.

3. The semiconductor die of claim 1, wherein the dissolvable metal layer includes cobalt.

4. The semiconductor die of claim 1, wherein the metal interface structure includes platinum.

5. The semiconductor die of claim 1, wherein the metal interface structure includes a noble metal selected from the group consisting of ruthenium, rhodium, palladium, osmium, and iridium.

6. The semiconductor die of claim 1, wherein the metal interface structure includes a non-noble metal capable of forming an alloy with tin.

7. The semiconductor die of claim 1, wherein the dissolvable metal layer is a first dissolvable metal layer, and the semiconductor die further comprises:
a surface component on a surface of the semiconductor substrate, the surface component coupled to the one or more metal layers; and
a second dissolvable metal layer on the surface component.

8. The semiconductor die of claim 7, wherein the first dissolvable metal layer and the second dissolvable metal layer include a same metal.

9. The semiconductor die of claim 8, wherein the first dissolvable metal layer and the second dissolvable metal layer are dissolvable in at least one of hydrochloric acid (HCl) or a solution of phosphoric acid, nitric acid, acetic acid, and water.

10. The semiconductor die of claim 7, wherein the surface component is between the second dissolvable metal layer and the one or more metal layers.

11. The semiconductor die of claim 1, wherein the dissolvable metal layer has a thickness of less than 5 kilo Angstroms.

12. An electronic device, comprising:
a substrate having a conductive terminal;
a semiconductor die including a metal interface structure;
a solder layer coupled to the conductive terminal of the substrate; and
an alloy metal interconnect coupled between the metal interface structure and the solder layer, the alloy metal interconnect including an alloy of solder and cobalt.

13. The electronic device of claim 12, wherein the alloy includes a metal of the metal interface structure.

14. The electronic device of claim 12, wherein the alloy is a first alloy, and the alloy metal interconnect includes a second alloy of the solder, cobalt, and a metal of the metal interface structure.

15. The electronic device of claim 12, wherein the substrate includes or is part of a printed circuit board (PCB).

16. The electronic device of claim 12, wherein a distance between the metal interface structure and the conductive terminal is less than 10 microns.

17. The electronic device of claim 12, wherein the semiconductor die includes:
a surface component on a surface of the semiconductor die; and
a dissolvable metal layer on the surface component.

18. The electronic device of claim 17, wherein the surface component includes a microelectromechanical system (MEMS).

19. The electronic device of claim 17, wherein the dissolvable metal layer comprises cobalt.

20. The electronic device of claim 17, wherein the dissolvable metal layer is dissolvable in at least one of solder and an acid.

21. A method, comprising:
forming circuitry in a semiconductor substrate;
forming one or more metal layers on the semiconductor substrate, the one or more metal layers coupled to the circuitry;
forming a metal interface structure on the one or more metal layers, in which the metal interface structure has opposite first and second surfaces, and the first surface faces and is coupled to the one or more metal layers; and
depositing a dissolvable metal layer on the second surface.

22. The method of claim 21, wherein the dissolvable metal layer is a first dissolvable metal layer, and the method further comprises:
forming a surface component on a surface of the semiconductor substrate, the surface component coupled to the circuitry; and
forming a second dissolvable metal layer on the surface component.

23. The method of claim 22, wherein the first and second dissolvable metal layer are formed simultaneously or in a same operation.
